(19) United States
(12) Patent Application Publication
(10) Pub. No.: US 2026/0293290 A1
(43) Pub. Date: Sep. 24, 2026

(54) SEMICONDUCTOR DEVICE INCLUDING DEEP TRENCH CAPACITOR

(71) Applicant: DB HiTek Co., Ltd., Bucheon-si (KR)

(72) Inventors: Chang Hun HAN, Icheon-si (KR); In Geun YEO, Seoul (KR); Do Hee KIM, Eumseong-gun (KR); Dong Uk SHIN, Suwon-si (KR)

(21) Appl. No.: 19/207,976

(22) Filed: May 14, 2025

(30) Foreign Application Priority Data
Mar. 19, 2025 (KR) 10-2025-0035239

(51) Int. Cl. H10D 84/00; H10D 1/66; H10D 62/10

(52) U.S. Cl. CPC H10D 84/217; H10D 1/665; H10D 62/126

(57) ABSTRACT

A semiconductor device including a deep trench capacitor is configured such that deep trench capacitor patterns of multiple cells are symmetric to each other along a longitudinal central shaft and a widthwise central shaft of the cells, thereby preventing warpage due to tensile stresses applied to a substrate. The semiconductor device includes a cell comprising multiple unit cells, each of the multiple unit cells including multiple deep trench capacitors spaced from each other on a substrate, wherein the multiple unit cells are arranged in multiple rows and multiple columns.

### CROSS REFERENCE TO RELATED APPLICATION

The present application claims priority to Korean Patent Application No. 10-2025-0035239, filed on Mar. 19, 2025, in the Korean Intellectual Property Office, the disclosure of which is incorporated herein by reference.

### BACKGROUND OF THE INVENTION

### Field of Invention

The present disclosure relates to a semiconductor device including a deep trench capacitor and, more particularly, to a semiconductor device including a deep trench capacitor, wherein deep trench capacitor patterns of multiple cells are symmetric to each other along a longitudinal central shaft and a widthwise central shaft of the cells, thereby preventing warpage due to tensile stresses applied to a substrate.

### Description of the Related Art

The semiconductor industry has continued to develop semiconductor devices with reduced surface area to form a large number of devices on the same-sized substrate. The vertical device structure can significantly reduce surface area requirements for a large number of semiconductor devices. One type of vertical device commonly implemented on integrated chips is deep trench capacitors. The deep trench capacitors include one or more capacitor electrodes extending into a trench in a semiconductor substrate. The deep trench capacitors may be used for a variety of purposes, for example, as a decoupling capacitor configured to decouple one part of an electrical circuit, such as an interconnect, from another part of the circuit.

Among several problems in utilizing the deep trench capacitors, a problem of warpage is caused by tensile stresses applied a semiconductor substrate due to the structure of the deep trench. Furthermore, the above-mentioned problems can be exacerbated when multiple deep trenches are formed on a substrate to increase the capacitance of the deep trench capacitor.

In order to remove the above-mentioned problems, the inventor of the present disclosure would like to present a new type of semiconductor device including a deep trench capacitor with an improved structure, and details of which will be described below.

### Document of Related Art

### Patent Document

(Patent Document 1) Korean Patent Application Publication No. 10-2021-0111931 "Trench capacitor"

### SUMMARY OF THE INVENTION

Accordingly, the present disclosure has been made keeping in mind the above problems occurring in the related art, an objective of the present disclosure is to provide a semiconductor device including a deep trench capacitor, wherein deep trench capacitor patterns of multiple cells are symmetric to each other along a longitudinal central shaft and a widthwise central shaft of the cells, thereby canceling tensile stresses applied to a substrate and preventing warpage of the substrate.

The present disclosure may be realized by embodiments having following configuration in order to achieve the above-described objective.

According to an embodiment of the present disclosure, according to the present disclosure, a semiconductor device including a deep trench capacitor, including: a cell comprising multiple unit cells comprising multiple deep trench capacitors spaced from each other on a substrate, wherein the multiple unit cells may be located in multiple rows and multiple columns.

According to another embodiment of the present disclosure, at least one of the multiple deep trench capacitors may have a different extension length in a widthwise direction.

According to another embodiment of the present disclosure, in the semiconductor device including a deep trench capacitor of the present disclosure, the cell may have a deep trench capacitor planar structure substantially symmetric along a widthwise central shaft and a longitudinal central shaft of the cell.

According to another embodiment of the present disclosure, in the semiconductor device including a deep trench capacitor of the present disclosure, one of the multiple unit cells may include: a plurality of pattern areas spaced from each other in a longitudinal direction, wherein each pattern area may include: one or more basic patterns, wherein the basic patterns may include: a first pattern having multiple deep trenches spaced in a widthwise direction, wherein a widthwise length of an upper deep trench on a plan view may be greater than a widthwise length of a lower deep trench; and a second pattern spaced from the first pattern in the longitudinal direction, and having multiple deep trenches spaced from each other in the widthwise direction, wherein a widthwise length of an upper deep trench on the plan view may be shorter than a widthwise length of a lower deep trench.

According to another embodiment of the present disclosure, in the semiconductor device including a deep trench capacitor of the present disclosure, the number of the basic patterns of each pattern area in one unit cell may be different from another pattern area.

According to another embodiment of the present disclosure, in the semiconductor device including a deep trench capacitor of the present disclosure, in one unit cell, a longitudinally left pattern area on the plan view may have fewer or more basic patterns than the basic patterns included in a right pattern area.

According to another embodiment of the present disclosure, in the semiconductor device including a deep trench capacitor of the present disclosure, a longitudinal separation distance between deep trenches in one pattern area may have a substantially constant value.

According to another embodiment of the present disclosure, in the semiconductor device including a deep trench capacitor of the present disclosure, a longitudinal separation distance between a pair of adjacent deep trenches of a pair of adjacent pattern areas may have a greater value than a longitudinal separation distance between deep trenches in each pattern area.

According to another embodiment of the present disclosure, in the semiconductor device including a deep trench capacitor of the present disclosure, a separation distance between a longitudinally last-end deep trench and a boundary of an adjacent unit cell may be substantially half of the longitudinal separation distance between deep trenches in each unit pattern area.

According to another embodiment of the present disclosure, in the semiconductor device including a deep trench capacitor of the present disclosure, at least one of the multiple pattern areas may be configured so that the first pattern and the second pattern are alternated in the longitudinal direction.

According to another embodiment of the present disclosure, in the semiconductor device including a deep trench capacitor of the present disclosure, a semiconductor device including a deep trench capacitor including: a cell including multiple unit cells including multiple deep trench capacitors spaced from each other on a substrate, and arrayed in two rows by two columns, wherein each deep trench capacitor may include: a deep trench extending from a surface of the substrate to a predetermined depth; an insulator film provided on a bottom surface and an inner side wall of the deep trench; a conductive layer provided on the insulator film; and a dielectric layer provided on the conductive layer, and the cell may include: a first unit cell at a first row and a first column; a second unit cell at the first row and a second column; a third unit cell at the second row and the first column; and a fourth unit cell at the second row and the second column.

According to another embodiment of the present disclosure, in the semiconductor device including a deep trench capacitor of the present disclosure, a deep trench pattern of the first unit cell may be symmetric to a deep trench pattern of the second unit cell along a widthwise central shaft of the cell, and be symmetric to a deep trench pattern of the third unit cell along a longitudinal central shaft of the cell, and a deep trench pattern of the fourth unit cell may be symmetric to the deep trench pattern of the third unit cell along the widthwise central shaft of the cell, and be symmetric to the deep trench pattern of the second unit cell along the longitudinal central shaft of the cell..

According to another embodiment of the present disclosure, in the semiconductor device including a deep trench capacitor of the present disclosure, any unit cell of the first to fourth unit cells may include: a plurality of pattern areas in a longitudinal direction, wherein each pattern area may include: one or more basic patterns, wherein the basic patterns may include: multiple deep trenches spaced from each other, wherein the basic patterns may include: a first pattern in which a widthwise length of each deep trench becomes longer as it goes in a widthwise direction; and a second pattern in which a widthwise length of each deep trench becomes shorter as it goes in the longitudinal direction.

According to another embodiment of the present disclosure, in the semiconductor device including a deep trench capacitor of the present disclosure, the multiple pattern areas may have different numbers of the basic patterns from each other.

According to another embodiment of the present disclosure, in the semiconductor device including a deep trench capacitor of the present disclosure, each unit cell may be configured so that the number of the basic patterns in each pattern area becomes smaller or larger as it goes in the longitudinal direction.

According to another embodiment of the present disclosure, in the semiconductor device including a deep trench capacitor of the present disclosure, a separation distance between adjacent deep trenches in the widthwise direction may have a substantially constant value.

According to another embodiment of the present disclosure, in the semiconductor device including a deep trench capacitor of the present disclosure, a separation distance between a widthwise last-end deep trench and a boundary of an adjacent unit cell may be substantially half of the separation distance between adjacent deep trenches in the widthwise direction.

According to another embodiment of the present disclosure, in the semiconductor device including a deep trench capacitor of the present disclosure, the multiple deep trenches may have planar patterns that are symmetric to each other in the widthwise central shaft and the longitudinal central shaft of the cell.

According to another embodiment of the present disclosure, in the semiconductor device including a deep trench capacitor of the present disclosure, each conductive layer may be electrically connected to a metal wiring by a corresponding metal contact.

According to another embodiment of the present disclosure, in the semiconductor device including a deep trench capacitor of the present disclosure, each pattern area may include the first pattern and the second pattern arrayed so that they correspond one to one to each other.

The present disclosure has the following effects with the above-described configuration.

According to the present disclosure, the deep trench capacitor patterns of the multiple cells are symmetric to each other along the longitudinal central shaft and the widthwise central shaft of the cells, thereby canceling tensile stresses applied to the substrate, and preventing warpage of the substrate.

Meanwhile, it should be added that even if the effects are not explicitly mentioned herein, the effects described in the following specification expected by the technical features of the present disclosure and their potential effects can be treated as if they were described in the specifications of the present disclosure.

### BRIEF DESCRIPTION OF THE DRAWINGS

FIG. 1 is a plan view showing a semiconductor device including a deep trench capacitor according to an embodiment of the present disclosure;

FIG. 2 is a plan view of a cell from FIG. 1;

FIG. 3 is a sectional view of line AA' from FIG. 2;

FIG. 4 is a sectional view of line BB' from FIG. 2;

FIG. 5 is a plan view of a cell including a first unit cell according to a first embodiment of the present disclosure;

FIG. 6 is a plan view of a cell including a first unit cell according to a second embodiment of the present disclosure;

FIG. 7 is a plan view of a cell including a first unit cell according to a third embodiment of the present disclosure; and

FIG. 8 is a plan view of the cell including a first unit cell according to a fourth embodiment of the present disclosure.

### DETAILED DESCRIPTION OF THE DISCLOSURE

Hereinbelow, embodiments of the present disclosure will be described in detail with reference to accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

In addition, although the terms first, second, etc. may be used to describe various items such as various elements, regions, and/or parts, the items should not be limited by these terms.

Furthermore, it should be noted that in cases where a specific embodiment can be implemented differently, a specific process sequence may be performed differently from the sequence described below. For example, the two processes described sequentially may be performed substantially simultaneously or may be performed in the opposite sequence.

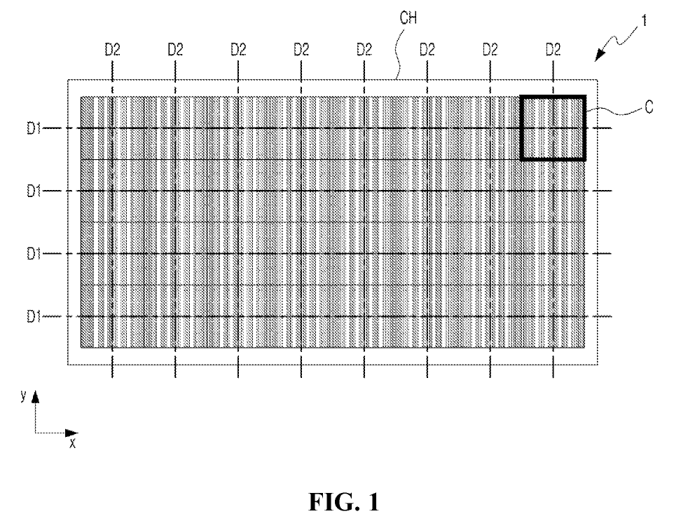

Hereinbelow, on the basis of a plan view shown, the x-axial direction is set as the "longitudinal direction", and the y-axial direction is set as the "widthwise direction". In the plan view shown in FIG. 1, a longitudinal value of a chip CH is set greater than a widthwise value, but the scope of the present disclosure is not limited thereto. The longitudinal value of the chip CH may be substantially equal to or less than the widthwise value, and there is no limitation thereto.

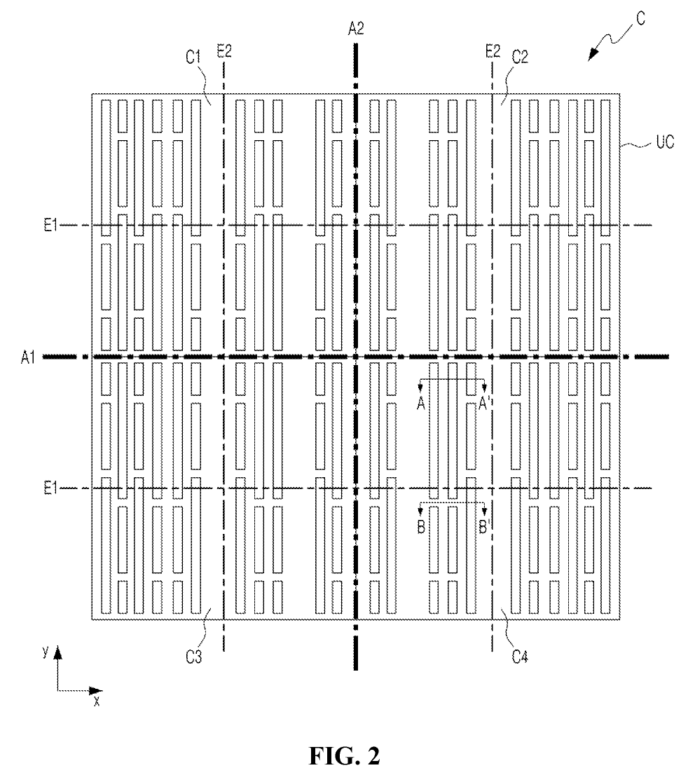

FIG. 1 is a plan view showing a semiconductor device including a deep trench capacitor according to an embodiment of the present disclosure, and FIG. 2 is a plan view of a cell from FIG. 1. For convenience of description, in FIG. 1 and plan views to be described below, it should be noted a metal wiring and a metal contact structure are omitted.

Hereinbelow, with reference to accompanying drawings, a semiconductor device 1 including a deep trench capacitor according to an embodiment of the present disclosure will be described in detail.

Referring to FIGS. 1 and 2, the present disclosure relates to a semiconductor device 1 including a deep trench capacitor and, more particularly, to a semiconductor device 1 including a deep trench capacitor, the semiconductor device being configured to have a pattern of a deep trench capacitor 110 in multiple cells C symmetric along a longitudinal central shaft and a widthwise central shaft of the cells, thereby preventing warpage due to tensile stresses applied to a substrate 101.

Hereinbelow, before describing the semiconductor device 1 including a deep trench capacitor according to the embodiment of the present disclosure, a structure of each deep trench capacitor 110 will be described in detail.

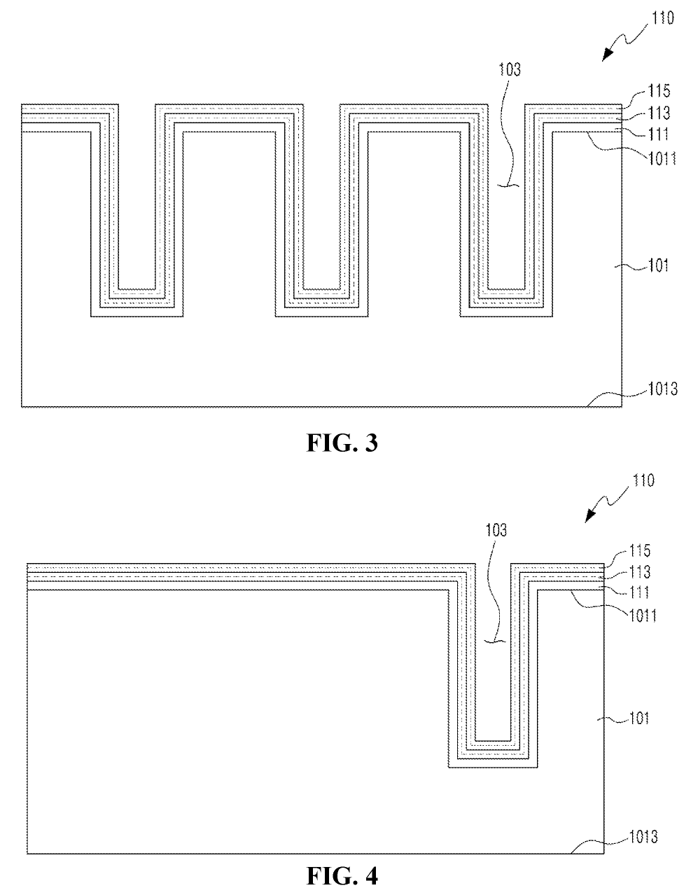

FIG. 3 is a sectional view of line AA' from FIG. 2, and FIG. 4 is a sectional view of line BB' from FIG. 2.

Referring to FIGS. 3 and 4, first, the deep trench capacitor 110 may be formed in the substrate 101. The substrate 101 may include, for example, a first surface 1011 and a second surface 1013 facing the first surface. Furthermore, at least a portion of the substrate 101 may be made of silicon. Furthermore, a deep trench 103 may be formed in the substrate 101.

The deep trench 103 may extend, for example, in a direction from the first surface 1011 of the substrate to the second surface 1013 to a predetermined depth. The deep trench 103 may be formed by, for example, the reactive ion etching (RIE) method, but there is no limitation thereto. Furthermore, the width of the deep trench 103 may be substantially uniform, become narrower, or become wider as it extends in the direction from the first surface 1011 to the second surface 1013, but there is no limitation thereto.

Furthermore, the deep trench capacitor 110 may be formed in the deep trench 103. First, an insulator film 111 may be formed on a bottom surface and an inner side wall of the deep trench 103. For example, the insulator film 111 may be a SiO2 film, and grown by thermal oxidation, but the scope of the present disclosure is not limited thereto. Furthermore, a conductive layer 113 may be formed on the insulator film 111 in the deep trench 103, and a dielectric layer 115 may be formed on the conductive layer 113.

The conductive layer 113 and the dielectric layer 115 may respectively be formed to be substantially conformal. The conductive layer 113 may include, for example, TiN, TaN, W, and poly Si layers. The dielectric layer 115 may include, for example, an oxide film and may be formed by, for example, the atomic layer deposition (ALD) process. The conductive layer 113 and the dielectric layer 115 may be stacked on each other alternately in the deep trench 103 a preset number of times. Multiple conductive layers 113 formed in each deep trench 103 may be provided to be parallel to each other. Furthermore, the insulator film 111, the conductive layer 113, and the dielectric layer 115 deposited on a portion of the substrate 101 outside the deep trench 103 may be removed, or remain on a portion of the substrate 101 outside the deep trench 103, but there is no limitation thereto.

Furthermore, one or more conductive layers 113 may be electrically connected to a metal wiring (not shown) by a metal contact (not shown). For example, when the deep trench capacitor 110 may include the multiple conductive layers 113, each conductive layer 113 may be connected to a corresponding metal contact to be connected to a corresponding metal wiring. Therefore, the deep trench capacitor 110 may include a structure in which multiple capacitors are connected to each other in parallel.

Hereinbelow, a semiconductor device 1 including a deep trench capacitor according to an embodiment of the present disclosure will be described in detail. According to the embodiment of the present disclosure, the semiconductor device 1, including a deep trench capacitor, is intended to cancel tensile stresses applied to the substrate 101 by an array structure of each deep trench capacitor 110.

Referring to FIG. 1, first, the semiconductor device 1 including a deep trench capacitor includes multiple cells C. Each cell C is an area including multiple deep trench capacitors 110 described above, and may be defined as a square area with reference to the plan view. The semiconductor device 1 including a deep trench capacitor may include multiple cells C that may be located in a widthwise direction and a longitudinal direction on the plan view.

When describing this in detail, a chip CH may be provided to include the multiple cells C arrayed in multiple rows D1 and multiple columns D2. Furthermore, an even number of cells C may be arrayed in a single row D1 and in a single column D2. In other words, an even number of cells C may be located in a single row D1 in the longitudinal direction, and an even number of cells C may be located in a single column D2. At this point, it is preferable to prevent each cell C from overlapping with another adjacent cell C.

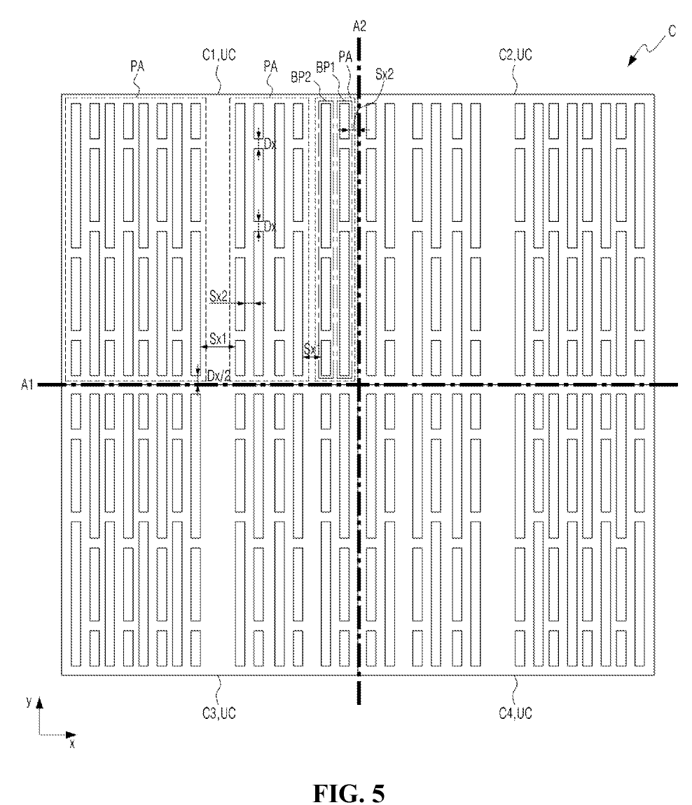

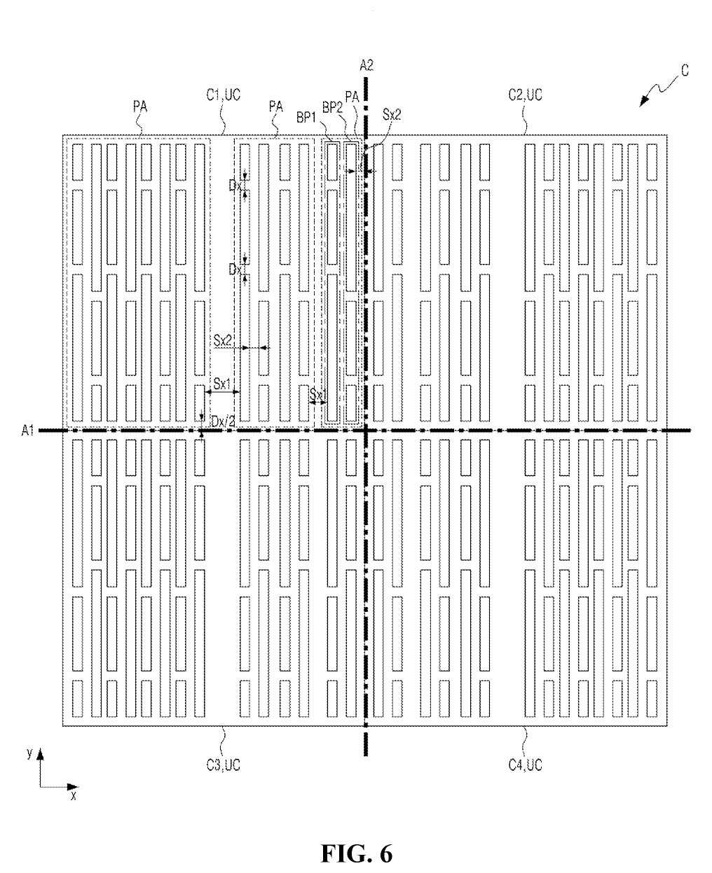

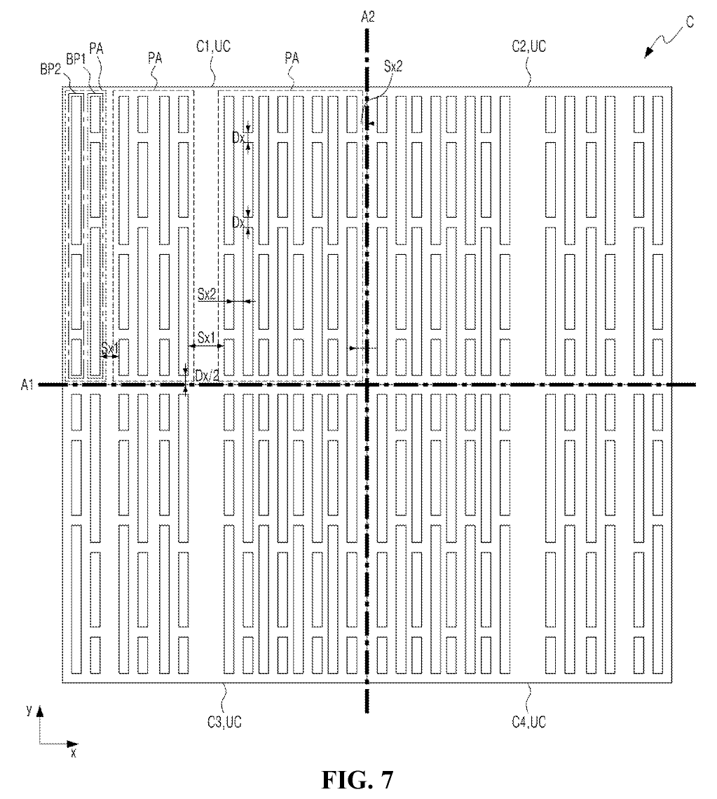

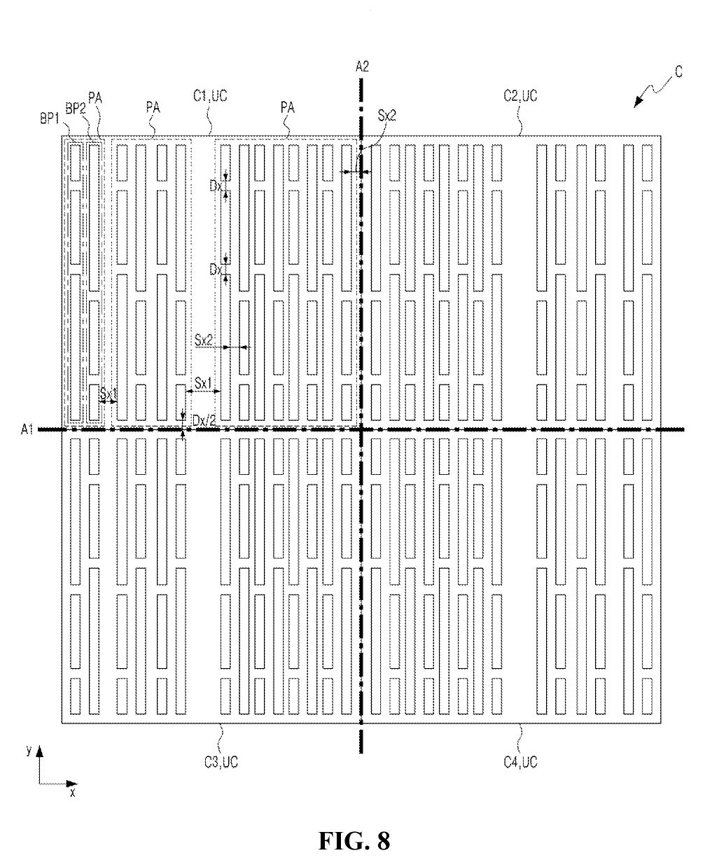

FIG. 5 is a plan view of a cell including a first unit cell according to a first embodiment of the present disclosure, FIG. 6 is a plan view of a cell including a first unit cell according to a second embodiment of the present disclosure, FIG. 7 is a plan view of a cell including a first unit cell according to a third embodiment of the present disclosure, and FIG. 8 is a plan view of a cell including a first unit cell according to a fourth embodiment of the present disclosure.

Referring to FIGS. 2 and 5 to 8, a single cell C may include multiple unit cells UC. In the single cell C, an even number of unit cells UC is located in each row E1 in the longitudinal direction, and an even number of unit cells UC may be located in each column E2. For example, with reference to the plan view, the single cell C may include four unit cells UC arrayed two by two.

Hereinbelow, when four unit cells UC are arrayed two by two in the single cell C, the cells UC are respectively referred to as a first unit cell C1, a second unit cell C2, a third unit cell C3, and a fourth unit cell C4. The first unit cell C1 is located at a first row and a first column, the second unit cell C2 is located at the first row and a second column, the third unit cell C3 is located at a second row and the 1 column, and the fourth unit cell C4 is located at the first row and the second column.

Furthermore, the structure of the multiple deep trenches 103 of the first unit cell C1 may be symmetric to the structure of the multiple deep trenches 103 of the second unit cell C2 along the widthwise central shaft A1 of the cells C on the plan view, and be symmetric to the structure of the multiple deep trenches 103 of the third unit cell C3 along the longitudinal central shaft A2.

Furthermore, the structure of the multiple deep trenches 103 of the fourth unit cell C4 may be symmetric to the structure of the multiple deep trenches 103 of the third unit cell C3 along the widthwise central shaft A1 of the cells C on the plan view, and be symmetric to the structure of the multiple deep trenches 103 of the second unit cell C2 along the longitudinal central shaft A2. Therefore, the structures of the deep trenches 103 may be symmetrically formed along the longitudinal central shaft A1 and the widthwise central shaft A2 of the cells C with reference to the plan view. Therefore, warpage applied to the substrate 101 can be removed by canceling tensile stresses applied to the substrate 101, which are based on each cell unit.

Hereinbelow, a structure of the first unit cell C1 will be described in detail. For convenience of description, the following structure will be described as being about the first unit cell C1, but the following structure may be the structure of one unit cell UC of the second unit cell C2 to the fourth unit cell C4, and there is no limitation thereto.

The first unit cell C1 may include multiple pattern areas PA. In the drawings, it is shown that the first unit cell C1 includes three pattern areas PA, but the scope of the present disclosure is not limited thereto. Furthermore, in the first unit cell C1, a pair of pattern areas PA adjacent to each other in the longitudinal direction may be spaced from each other at a predetermined distance.

At this point, the structure may be designed so that a separation distance SX1 between a pair of adjacent deep trenches 103 of a pair of pattern areas PA adjacent in the longitudinal direction may have a uniform value or a different value from values of other separation distances SX1, and there is no limitation thereto. As an example, when three or more pattern areas PA in the first unit cell C1 are separation distanced from each other in the longitudinal direction, the separation distance SX1 between a pair of adjacent deep trenches 103 of a pair of pattern areas PA at the left side on the plan view may have a value greater or less than a value of the separation distance SX1 between a pair of adjacent deep trenches 103 of another pair of pattern areas PA.

Furthermore, each pattern area PA may include one or more basic patterns BP. The basic patterns BP may include, for example, two pattern structures P. Each pattern structure P may be understood as relating to a form of forming the multiple deep trenches 103 in the substrate 101 in the widthwise direction on the plan view. More specifically, the pattern structure P may be a pattern in which the widthwise length of the deep trench 103 becomes greater or smaller as it goes in the widthwise direction when the multiple deep trenches 103 are formed in the widthwise direction on the plan view in the pattern area PA. The above-described two pattern structures P are referred to as a first pattern BP1 and a second pattern BP2.

The first pattern BP1 may have multiple deep trenches 103 spaced from each other in the widthwise direction on the plan view, and have the widthwise length of each deep trench 103 that becomes greater as it goes downwards. In other words, at the same longitudinal coordinate value, when the multiple deep trenches 103 are formed to be spaced from each other in the widthwise direction, a lower deep trench 103 of the multiple deep trenches may have a greater widthwise length than an upper deep trench 103. For example, at the same longitudinal coordinate value, when three deep trenches 103 are formed to be spaced from each other, the uppermost deep trench 103 on the plan view has the shortest widthwise length, and the lowermost deep trench 103 has the longest widthwise length. Hereinabove, the "upper side" and the "lower side" mean an upper side and a lower side in the y-axial direction (or widthwise direction) based on the plane views, and does not mean vertical relationship based on the z-axial direction.

Unlike the above example, the first pattern BP1 may have four or more deep trenches 103 in the widthwise direction, and there is no limitation thereto. Furthermore, a separation distance DY between a pair of deep trenches 103 adjacent to each other in the widthwise direction in the first pattern BP1 may have a uniform value, or at least one separation distance DY may have a different value from other separation distances DY, and there is no limitation thereto.

Furthermore, in the second pattern BP2, the multiple deep trenches 103 are spaced from each other in the widthwise direction on the plan view, and may have the widthwise length of the deep trench 103 that becomes shorter as it goes to upper side (in upper direction on plan view). In other words, the second pattern BP2 may have a planar shape of the deep trench 103 inverted upside down with the first pattern BP1 on the plan view. Furthermore, a separation distance DY between a pair of deep trenches 103 adjacent to each other in the widthwise direction in the second pattern BP2 may have a uniform value, or at least one separation distance DY may have a different value from other separation distances DY, and there is no limitation thereto.

Furthermore, one or more first patterns BP1 and one or more second patterns BP2 are arrayed in each pattern area PA to be spaced from each other in the longitudinal direction. When the pattern area PA includes multiple first patterns BP1 and multiple second patterns BP2, in the pattern area PA, the first patterns BP1 and the second patterns BP2 may be alternated in the longitudinal direction.

As an example, when the multiple pattern areas PA are formed to be spaced from each other in the longitudinal direction in the first unit cell C1, the number of basic patterns BP of each pattern area PA may become smaller as it goes in a rightward direction on the plan view. As an example, as shown in the drawings, in the first unit cell C1, the leftmost pattern area PA has four basic patterns BP, and the pattern area PA at the right side of the leftmost one has two basic patterns BP, and the rightmost pattern area PA may have one basic pattern BP.

Contrary to the description, when the multiple pattern areas PA are formed to be spaced from each other in the longitudinal direction in the first unit cell C1, the number of basic patterns BP of each pattern area PA may become greater as it goes in a rightward direction on the plan view.

At this point, it is preferable that the same number of first patterns BP1 and the same number of second patterns BP2 are formed in a single pattern area PA. In other words, when two first patterns BP1 are formed in any pattern area PA, two second patterns BP2 may also be formed.

Furthermore, it is preferable that the separation distance SX2 between the deep trenches 103 in the longitudinal direction in a single pattern area PA may have a uniform value within a fabrication error range. Furthermore, it is preferable that a separation distance between the longitudinally last-end deep trench 103 in the single cell C and a boundary of an adjacent cell C is a half value of SX2. Therefore, a separation distance between the longitudinally last-end deep trench 103 in the single cell C and an adjacent trench 103 in another adjacent cell C may be a value of SX2.

Furthermore, it is preferable that a separation distance between the widthwise last-end deep trench 103 and a boundary of an adjacent cell C is a half value of DY. Therefore, a separation distance between the widthwise last-end deep trench 103 in the single cell C and an adjacent trench 103 in another adjacent cell C may be DY.

The pattern of the deep trenches 103 in each unit cell UC relates to the first unit cell C1 and is described for illustrative purposes, and as described above, the above pattern may be one of the second to fourth unit cells C2 to C4. In other words, the above pattern may be about any unit cell UC as long as it satisfies the rule in which the first unit cell C1 is symmetric to the second unit cell C2 along the widthwise central shaft A1 of the cells C and symmetric to the third unit cell C3 along the longitudinal central shaft A2, and the fourth unit cell C4 is symmetric to the third unit cell C3 along the widthwise central shaft A1 of the cells C and symmetric to the second unit cell C2 along the longitudinal central shaft A2.

As described above, the multiple unit cells UC in the cell C are formed with the pattern of the deep trenches 103 symmetric widthwise and longitudinally on the plan views so that tensile stresses applied to the substrate 101 by the trenches 103 can be mutually canceled.

The detailed description above is illustrative of the present disclosure. In addition, the above description shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiments describe the best state for implementing the technical spirit of the present disclosure, and various changes required in the specific application field and use of the present disclosure are possible. Accordingly, the detailed description of the present disclosure is not intended to limit the present disclosure to the disclosed embodiments.

What is claimed is:

1. A semiconductor device including a deep trench capacitor, the semiconductor device comprising:
a cell comprising multiple unit cells, each of the multiple unit cells comprising multiple deep trench capacitors spaced from each other on a substrate,
wherein the multiple unit cells are arranged in multiple rows and multiple columns.

2. The semiconductor device of claim 1, wherein at least one of the multiple deep trench capacitors has a different extension length in a widthwise direction of the cell.

3. The semiconductor device of claim 1, wherein the cell has a deep trench capacitor planar structure substantially symmetric with respect to a widthwise central shaft and a longitudinal central shaft of the cell.

4. The semiconductor device of claim 3, wherein one of the multiple unit cells comprises:
a plurality of pattern areas spaced from each other in a longitudinal direction of the cell,
wherein each pattern area comprises:
one or more basic patterns,
wherein the one or more basic patterns comprise:
a first pattern having multiple deep trenches spaced in a widthwise direction of the cell, wherein a widthwise length of an upper deep trench on a plan view is greater than a widthwise length of a lower deep trench; and
a second pattern spaced from the first pattern in the longitudinal direction of the cell, and having multiple deep trenches spaced from each other in the widthwise direction, wherein a widthwise length of an upper deep trench of the second pattern on the plan view is shorter than a widthwise length of a lower deep trench of the second pattern.

5. The semiconductor device of claim 4, wherein in the one of the multiple unit cells, a number of the one or more basic patterns of each pattern area is different from another pattern area.

6. The semiconductor device of claim 4, wherein in the one of the multiple unit cells, a pattern area disposed left to another pattern area in the longitudinal direction on the plan view has a fewer or greater number of the one or more basic patterns than a number of the one or more basic patterns included in the another pattern area.

7. The semiconductor device of claim 4, wherein a longitudinal separation distance between adjacent deep trenches in one pattern area has a substantially constant value.

8. The semiconductor device of claim 4, wherein a longitudinal separation distance between one deep trench in one pattern area and another deep trench adjacent to the one deep trench in another pattern area has a greater value than a longitudinal separation distance between deep trenches in the one pattern area.

9. The semiconductor device of claim 7, wherein a longitudinal separation distance between a deep trench disposed at a last end of one unit cell in the longitudinal direction and a boundary of an adjacent unit cell is substantially half of the longitudinal separation distance between the adjacent deep trenches in the one pattern area.

10. The semiconductor device of claim 4, wherein at least one of the plurality of pattern areas is configured so that the first pattern and the second pattern are alternated in the longitudinal direction.

11. A semiconductor device including a deep trench capacitor, the semiconductor device comprising:
a cell comprising multiple unit cells, each of the multiple unit cells comprising multiple deep trench capacitors spaced from each other on a substrate, the multiple unit cells being arrayed in two rows by two columns,
wherein each deep trench capacitor comprises:
a deep trench extending from a surface of the substrate to a predetermined depth; an insulator film disposed on a bottom surface and an inner side wall of the deep trench; a conductive layer disposed on the insulator film; and a dielectric layer disposed on the conductive layer, and
wherein the cell comprises:
a first unit cell at a first row and a first column; a second unit cell at the first row and a second column; a third unit cell at a second row and the first column; and a fourth unit cell at the second row and the second column.

12. The semiconductor device of claim 11, wherein a deep trench pattern of the first unit cell is symmetric to a deep trench pattern of the second unit cell along a widthwise central shaft of the cell, and the deep trench pattern of the first unit cell is symmetric to a deep trench pattern of the third unit cell along a longitudinal central shaft of the cell, and
wherein a deep trench pattern of the fourth unit cell is symmetric to the deep trench pattern of the third unit cell along the widthwise central shaft of the cell, and the deep trench pattern of the fourth unit cell is symmetric to the deep trench pattern of the second unit cell along the longitudinal central shaft of the cell.

13. The semiconductor device of claim 12, wherein each of the first to fourth unit cells comprises:
a plurality of pattern areas spaced apart from each other in a longitudinal direction,
wherein each pattern area comprises:
one or more basic patterns,
wherein each of the one or more basic patterns comprises:
multiple deep trenches spaced from each other,
wherein each of the one or more basic patterns comprises:
a first pattern in which a widthwise length of each deep trench becomes greater as each deep trench is positioned farther along a widthwise direction from a lower side or from an upper side on a plan view; or
a second pattern in which the widthwise length of each deep trench becomes shorter as each deep trench is positioned farther along the longitudinal direction from a left side or from a right side on the plan view.

14. The semiconductor device of claim 13, wherein each of the plurality of pattern areas has a different number of the one or more basic patterns from another pattern area.

15. The semiconductor device of claim 13, wherein each unit cell is configured so that a number of the one or more basic patterns in each pattern area becomes smaller or larger as each pattern area is positioned farther along the longitudinal direction from the left side or the right side on the plan view.

16. The semiconductor device of claim 12, wherein a separation distance between adjacent deep trenches in a widthwise direction has a substantially constant value.

17. The semiconductor device of claim 16, wherein a separation distance between a widthwise last-end deep trench and a boundary of an adjacent unit cell is substantially half of the separation distance between the adjacent deep trenches in the widthwise direction.

18. The semiconductor device of claim 12, the cell has planar patterns of multiple deep trenches that are symmetric to each other with respect to the widthwise central shaft and the longitudinal central shaft of the cell.

19. The semiconductor device of claim 12, wherein the conductive layer is electrically connected to a metal wiring by a corresponding metal contact.

20. The semiconductor device of claim 13, wherein each pattern area comprises the first pattern and the second pattern arrayed so that the first pattern and the second pattern correspond one to one to each other.
